(19) United States
(12) Patent Application Publication
(10) Pub. No.: US 2016/0268355 A1
(43) Pub. Date: Sep. 15, 2016

(54) DISPLAY SUBSTRATE HAVING PIXEL DEFINING LAYER AND PREPARATION METHOD, AND DISPLAY APPARATUS COMPRISING THE SAME

(71) Applicant: BOE TECHNOLOGY GROUP CO., LTD, Beijing (CN)

(72) Inventors: Shoulei SHI, Beijing (CN); Ze LIU, Beijing (CN)

(73) Assignee: BOE TECHNOLOGY GROUP CO., LTD, Beijing (CN)

(21) Appl. No.: 14/907,712

(22) PCT Filed: Jul. 28, 2015
(86) PCT No.: PCT/CN2015/085301

§ 371 Date: Jan. 26, 2016

(30) Foreign Application Priority Data
Mar. 12, 2015 (CN) 201510108888.5

(51) Int. Cl. H01L 27/32; H01L 51/00; H01L 51/56

(52) U.S. Cl. CPC H01L 27/3246; H01L 27/3283; H01L 51/56; H01L 51/0094; H01L 2251/301; H01L 2251/303; H01L 2227/323; H01L 51/005

(57) ABSTRACT

A method for preparing a display substrate, including forming a pixel defining layer (20) on a substrate (100), wherein forming the pixel defining layer (20) includes: forming a basic pattern (200) of the pixel defining layer on the substrate (100); the basic pattern (200) of the pixel defining layer comprises a first pattern (200a) of inorganic material, the first pattern (200a) being a top part of the basic pattern (200) of the pixel defining layer; subjecting the first pattern (200a) to a surface treatment with a self-assembled monomolecular layer to form a fluorinated monomolecular layer (210) on the surface of the first pattern, thereby forming the pixel defining layer (20). The lyophobic performance of the pixel defining layer formed by the method may be maintained for a long time.

### TECHNICAL FIELD

Embodiments of the present invention relate to a display substrate having a pixel defining layer and a preparation method, and a display apparatus comprising the same.

### BACKGROUND ART

Over recent years, researchers have been attempting to apply ink-jet printing technology to the preparation of planar functional materials, such as the preparation of organic material functional layers of an organic electroluminescent light-emitting diode display, the preparation of a color filter layer of a liquid crystal display and the like. It is generally required to prepare a pixel defining layer in a display substrate.

### SUMMARY OF THE INVENTION

Embodiments of the present invention provide a display substrate comprising a pixel defining layer and a preparation method, and a display apparatus comprising the same, which may enable the lyophobic performance of the pixel defining layer to be maintained for a long time.

In order to achieve the above object, embodiments of the present invention employ the following technical solutions.

A display substrate comprising a pixel defining layer, wherein

the pixel defining layer comprises: a basic pattern of the pixel defining layer comprising a first pattern of inorganic material, the first pattern being a top part of the basic pattern of the pixel defining layer; and

the pixel defining layer further comprises: a fluorinated monomolecular layer self-assembled on a surface of the first pattern.

In one aspect, a method for preparing a pixel defining layer comprises: forming a basic pattern of the pixel defining layer on a substrate; the basic pattern of the pixel defining layer comprises a first pattern of inorganic material, the first pattern being a top part of the basic pattern of the pixel defining layer; subjecting the first pattern to a surface treatment with a self-assembled monomolecular layer to form a fluorinated monomolecular layer on a surface of the first pattern, and thus form the pixel defining layer.

In some embodiments, subjecting the first pattern to a surface treatment with a self-assembled monomolecular layer comprises: forming a photosensitive organic resin layer between the basic pattern of the pixel defining layer, the photosensitive organic resin layer exposing the first pattern; subjecting the first pattern exposed to the surface treatment with the self-assembled monomolecular layer; after the fluorinated monomolecular layer has been formed on the surface of the first pattern, the method further comprises: removing the photosensitive organic resin layer.

On such a basis, one possible implementation is that: forming a basic pattern of the pixel defining layer on a substrate comprises: forming a first film of inorganic material on the substrate; and subjecting the first film to a patterning process to form the basic pattern of the pixel defining layer that is comprised of the first pattern and a second pattern.

In some embodiments, “forming a photosensitive organic resin layer between the basic pattern of the pixel defining layer, the photosensitive organic resin layer exposing the first pattern” comprises: forming a second film of photosensitive organic resin material on the substrate on which the basic pattern of the pixel defining layer is formed, the second film covering the basic pattern of the pixel defining layer; and etching the second film by plasma to expose the first pattern such that the second film between the basic pattern of the pixel defining layer is formed into the photosensitive organic resin layer.

Another possible implementation is that: forming the basic pattern of the pixel defining layer on the substrate comprises: forming the basic pattern of the pixel defining layer that is comprised of the first pattern and a third pattern of organic material on the substrate.

In some embodiments, forming the basic pattern of the pixel defining layer that is comprised of the first pattern and the third pattern of organic material on the substrate comprises: sequentially forming a third film of negative photosensitive organic resin material, a fourth film of inorganic material and a fifth film of negative photosensitive organic resin material on the substrate; exposing the substrate on which the third film, the fourth film and the fifth film are formed by using an ordinary mask such that a cured portion in the third film forms the third pattern and a cured portion in the fifth film forms a fifth pattern, and removing the uncured portion in the fifth film after development; and etching the fourth film by using the fifth pattern as a mask to form the first pattern; wherein the third pattern and the first pattern constitute the basic pattern of the pixel defining layer;

forming the photosensitive organic resin layer between the basic pattern of the pixel defining layer comprises: forming an uncured portion in the third film into the photosensitive organic resin layer after removing the fifth pattern.

In view of the foregoing, in some embodiments, the first pattern is subjected to a surface treatment with a self-assembled monomolecular layer by using a fluorosilane; before subjecting the first pattern to the surface treatment with the self-assembled monomolecular layer by using the fluorosilane, the method further comprises: subjecting the first pattern to a hydroxylation treatment.

In a further aspect, a pixel defining layer comprises: a basic pattern of the pixel defining layer comprising a first pattern of inorganic material, the first pattern being a top part of the basic pattern of the pixel defining layer; and further comprises: a fluorinated monomolecular layer self-assembled on a surface of the first pattern.

In some embodiments, the basic pattern of the pixel defining layer comprises the first pattern of inorganic material and a second pattern of inorganic material, and the first pattern and the second pattern are formed integrally.

In some embodiments, the basic pattern of the pixel defining layer comprises the first pattern of inorganic material and a third pattern of organic material.

In some embodiments, a material of the third pattern is a photosensitive organic resin material after being cured.

In a further aspect, a display substrate is provided, which comprises the pixel defining layer as described above.

In a further aspect, a method for preparing a display substrate is provided, which comprises forming a pixel defining layer on a substrate, wherein the method for preparing the pixel defining layer is the method for preparing the pixel defining layer as described above.

In a further aspect, a display apparatus is provided, which comprises the display substrate as described above.

Embodiments of the present invention provide a pixel defining layer and a method for preparing the same, a display substrate and a method for preparing the same, and a display apparatus, the method for preparing a pixel defining layer comprising: forming a basic pattern of the pixel defining layer on a substrate; the basic pattern of the pixel defining layer comprises a first pattern of inorganic material, the first pattern being a top part of the basic pattern of the pixel defining layer; subjecting the first pattern to a surface treatment with a self-assembled monomolecular layer, to form a fluorinated monomolecular layer on a surface of the first pattern, and thus form the pixel defining layer. Since the self-assembled fluorinated monomolecular layer is connected to the first pattern through a covalent bond, placement over a long period of time, a common cleaning step (other than plasma), and processes such as annealing will not affect the lyophobic performance thereof. Therefore, the lyophobic performance of the pixel defining layer formed by such a method can be maintained for a long time without worrying about out-of-service thereof. In addition, the contact angle of the self-assembled fluorinated monomolecular layer may achieve up to 110° C.

### BRIEF DESCRIPTION OF THE DRAWINGS

In order to illustrate the technical solutions of the embodiments of the present invention more clearly, the drawings of the embodiments are simply described below. Apparently, the drawings described below relate to only some embodiments of the present invention and are not limitative of the present invention.

FIG. 1 is a schematic top view of an organic electroluminescent light-emitting diode display.

FIG. 2 is a schematic structural view of a pixel defining layer.

FIGS. 3a-3b are schematic view I of a process for preparing a pixel defining layer according to an embodiment of the present invention.

FIG. 4 is a schematic view of the principle for self-assembling fluorooctyl trichlorosilane on a first pattern of inorganic material according to an embodiment of the present invention.

FIGS. 5a-5b are schematic view II of a process for preparing a pixel defining layer according to an embodiment of the present invention.

FIG. 6 is a schematic view of a process for forming a photosensitive organic resin layer between a basic pattern of a pixel defining layer according to an embodiment of the present invention.

FIGS. 7a-7e are schematic view III of the process for preparing a pixel defining layer according to an embodiment of the present invention.

FIGS. 8a-8d are schematic views of a process for preparing a display substrate for organic light-emitting diode (OLED) according to an embodiment of the present invention.

### DESCRIPTION OF REFERENCE SIGNS

01—pixel region; 02—non-pixel region; 20—pixel defining layer; 100—substrate; 200—basic pattern of pixel defining layer; 200a—first pattern; 200b—second pattern; 210—fluorinated monomolecular layer; 300—(photosensitive) organic resin layer; 300a—second film of photosensitive organic resin material; 400—third film of negative photosensitive organic resin material; 400a—third pattern; 500—fourth film of inorganic material; 600—fifth film of negative photosensitive organic resin material; 600a—fifth pattern; 700—first electrode; 800—organic material functional layer; 900—second electrode layer.

### DETAILED DESCRIPTION

To make clearer the objects, technical solutions and advantages of the embodiments of the present invention, a clear and full description of the technical solutions of the embodiments of the present invention will be made with reference to the accompanying drawings of the embodiments of the present invention. Obviously, the embodiments described are merely part of rather than all of the embodiments of the present invention. Based on the embodiments of the present invention described, all the other embodiments acquired by a person of ordinary skill in the art, without any creative labor, fall within the scope of protection of the present invention.

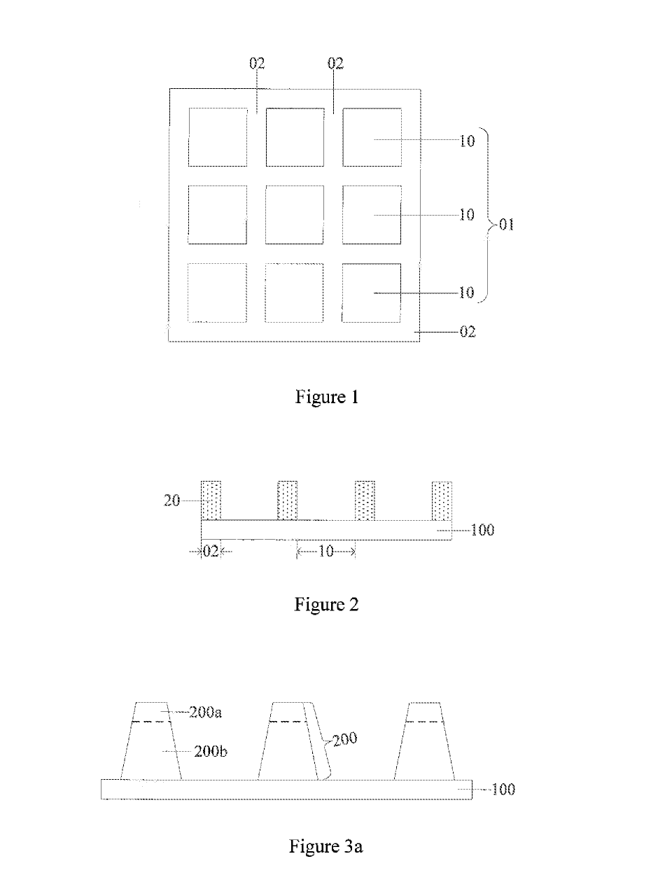

Taking an organic electroluminescent light-emitting diode display (OLED) as an example, as shown in FIG. 1 and FIG. 2, the organic electroluminescent light-emitting diode comprises a pixel and a non-pixel region 02, the pixel region 01 consisting of a plurality of pixels 10, wherein each pixel 10 comprises an anode, an organic material functional layer and a cathode disposed sequentially on a substrate 100 (not shown in FIG. 1 and FIG. 2). Upon forming the organic material functional layer on the anode by ink-jet printing, due to the flowability of ink and in order to reduce overflow of the ink that is ink-jet printed to the adjacent pixel 10, a pixel defining layer 20 is typically provided in the non-pixel region 02 to form a plurality of spaces surrounding each pixel 10, the ink of the organic material functional layer ink-jet printed being sprayed in the above surrounding spaces by ink-jet printing, i.e., being sprayed on the anode surface.

The pixel defining layer 20 consists of a basic pattern of the pixel defining layer formed on the substrate 100. In order to achieve lyophobicity of the pixel defining layer 20, currently the most conventional lyophobic treatment method is to subject the above basic pattern of the pixel defining layer to a fluorine-containing plasma treatment. However, due to the characteristics of plasma, its performance generally cannot be held for a long time. As such, ineffectiveness may be caused upon carrying out a preparation process for a long time or an annealing process at high temperatures.

Embodiments of the present invention provide a method for preparing a pixel defining layer, comprising:

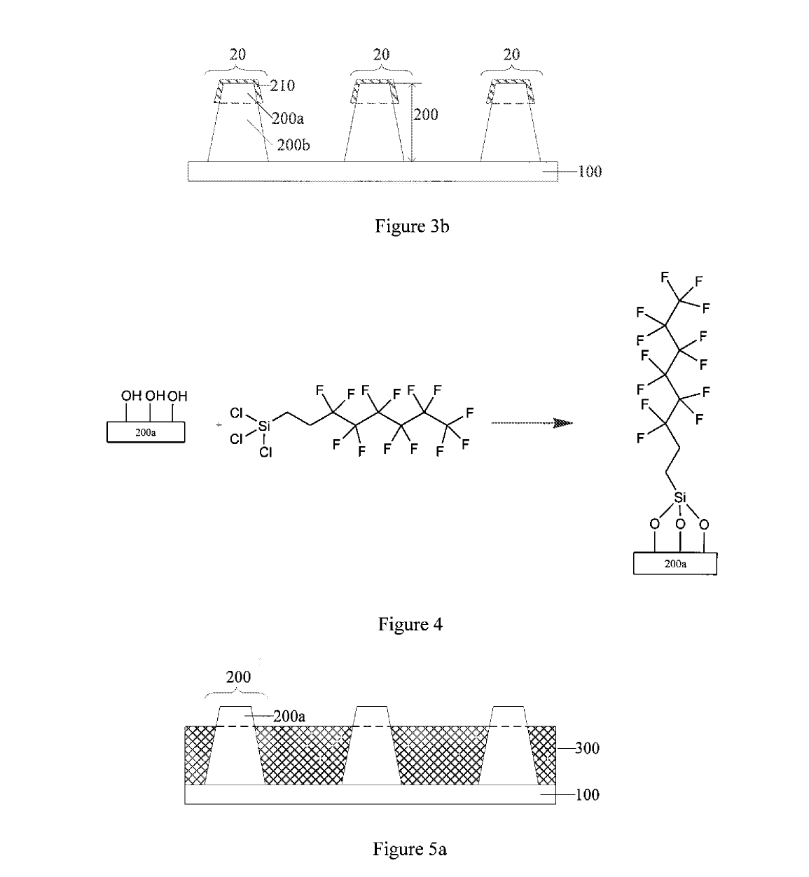

S01. as shown in FIG. 3a, forming a basic pattern 200 of the pixel defining layer on a substrate 100; the basic pattern 200 of the pixel defining layer comprises a first pattern 200a of inorganic material, the first pattern 200a being a top part of the basic pattern 200 of the pixel defining layer.

That is, the basic pattern 200 of the pixel defining layer further comprises other patterns in addition to the first pattern 200a, the first pattern being located on or above the other patterns.

“The basic pattern 200 of the pixel defining layer comprises a first pattern 200a of inorganic material, the first pattern 200a being a top part of the basic pattern 200 of the pixel defining layer” may be that the basic pattern 200 of the pixel defining layer further comprises a second pattern 200b of inorganic material in addition to the first pattern 200a of inorganic material, the first pattern 200a being located on or above the second pattern 200b.

Herein, under the circumstance that the first pattern 200a and the second pattern 200b of the basic pattern 200 of the pixel defining layer have a same material, the basic pattern 200 of the pixel defining layer can be formed by a same inorganic material film, i.e., a thickness of the inorganic material film of the layer is a sum of the thicknesses of the first pattern 200a and the thicknesses of the second pattern 200b. In this case, distinguishing between the first pattern 200a and the second pattern 200b is merely for subsequently describing the structure of the fluorinated monomolecular layer 210 in a convenient way. The dash lines that distinguish between the first pattern 200a and the second pattern 200b in FIG. 3a and FIG. 3b actually do not exist.

Of course, under the circumstance that the first pattern 200a and the second pattern 200b of the basic pattern 200 of the pixel defining layer have a same material, the basic pattern 200 of the pixel defining layer can also be formed by two inorganic material films, i.e., one of the inorganic material films is used for forming the first pattern 200a and the other inorganic material film is used for forming the second pattern 200b, which may specifically depends upon actual conditions and no limitation will be made herein.

Alternatively, “the basic pattern 200 of the pixel defining layer comprises a first pattern 200a of inorganic material, the first pattern 200a being a top part of the basic pattern 200 of the pixel defining layer” may also be that the basic pattern 200 of the pixel defining layer further comprises, in addition to the first pattern 200a of inorganic material, a third pattern of other material such as organic material, the first pattern 200a being located on or above the third pattern. In this case, a difference between the second pattern 200b and the third pattern merely lies in the material.

Of course, embodiments of the present invention do not limit to that in addition to the first pattern 200a of inorganic material, the basic pattern 200 of the pixel defining layer comprises only a third pattern, but the basic pattern 200 of the pixel defining layer also comprises other patterns as long as these patterns can constitute the basic pattern 200 of the pixel defining layer, where the first pattern 200a is the top part thereof.

On the basis of the above circumstances, settings may be made depending upon actual conditions and no limitation will be made herein.

S02. As shown in FIG. 3b, subjecting the first pattern 200a to a surface treatment with a self-assembled monomolecular layer to form a fluorinated monomolecular layer 210 on a surface of the first pattern 200a, and thus form the pixel defining layer 20.

Herein, a person skilled in the art should know that after self-assembling, the fluorinated monomolecular layer 210 is connected to the first pattern 200a via a covalent bond.

In some embodiments, fluorosilane such as fluorooctyl trichlorosilane is selected as a self-assembled lyophobic material to subject the first pattern 200a to a self-assembled surface treatment; the principle for self-assembling the material is as shown in FIG. 4. The fluorosilane may have a formula of Si(R1)₄, wherein each R1 is independently selected from the group consisting of halogen and fluoroalkyl, and at least one R1 is halogen and at least one R1 is fluoroalkyl. In some embodiments, two R1 are halogen and two R1 are fluoroalkyl. In some embodiments, three R1 are halogen and one R1 is fluoroalkyl. In some embodiments, one R1 is halogen and three R1 are fluoroalkyl.

In some embodiments, the halogen is selected from the group consisting of F, Cl, Br and I. In some embodiments, the fluoroalkyl is fluoro C1-20 alkyl. In some embodiments, the fluoroalkyl is fluoro C3-18 alkyl. In some embodiments, the fluoroalkyl is fluoro C4-12 alkyl.

The fluorooctyl trichlorosilane has the following formula:

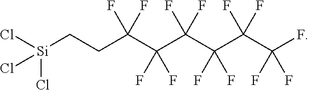 [SMILES: FC(F)(F)C(F)(F)C(F)(F)C(F)(F)C(F)(F)C(F)(F)CC[Si](Cl)(Cl)Cl]

In some embodiments, the substrate on which the first pattern 200a is formed is placed in a fluorooctyl trichlorosilane atmosphere to be held for 2 hours at a temperature ranging from 100-250° C.

It shall be noted that firstly, the above substrate 100 has no limitation, and may be either a substrate on which a corresponding pattern layer is formed or a base substrate on which no pattern layer is formed.

Secondly, the thickness of the first pattern 200a has no limitation, and may be set depending upon the actual condition.

Thirdly, because the pixel defining layer in the prior art is not additionally provided with the fluorinated monomolecular layer 210, the basic pattern 200 of the pixel defining layer in the embodiments of the present invention is substantively the pixel defining layer as described in the prior art.

Embodiments of the present invention provide a method for preparing a pixel defining layer, comprising: forming a basic pattern 200 of the pixel defining layer on a substrate 100; the basic pattern 200 of the pixel defining layer comprises a first pattern 200a of inorganic material, the first pattern 200a being a top part of the basic pattern 200 of the pixel defining layer; subjecting the first pattern 200a to a surface treatment with a self-assembled monomolecular layer to form a fluorinated monomolecular layer 210 on the surface of the first pattern 200a, and thus form the pixel defining layer 20. Because the self-assembled fluorinated monomolecular layer 210 is connected to the first pattern 200a via a covalent bond, placement over a long period of time, a general cleaning step (other than plasma), and processes such as annealing will not affect the lyophobic performance thereof. Therefore, the lyophobic performance of the pixel defining layer 20 formed by such a method can be maintained for a long time without worrying about out-of-service thereof. In addition, the contact angle of the self-assembled fluorinated monomolecular layer 210 may achieve up to 110° C.

In some embodiments, the above S02 may specifically comprise the steps of:

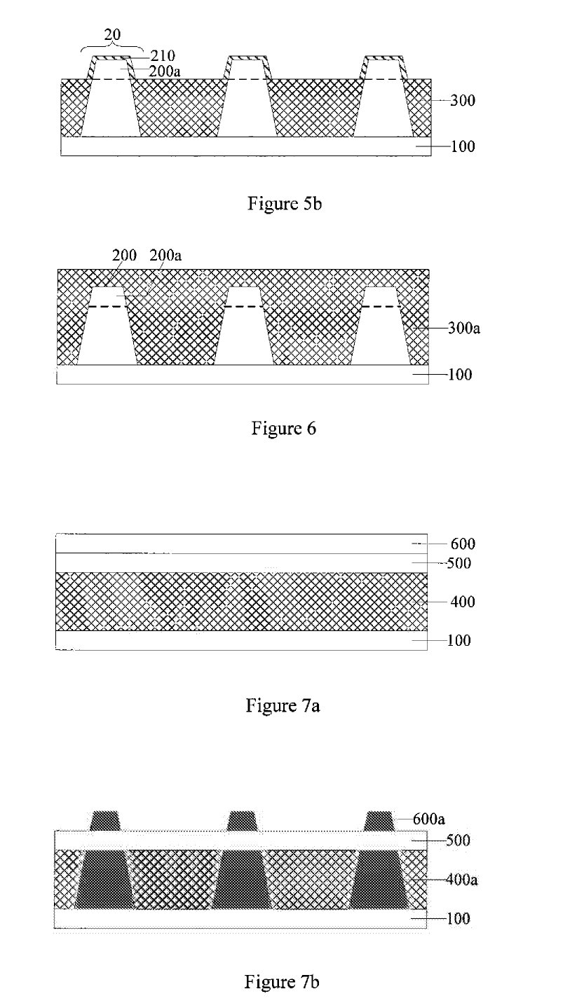

S201. As shown in FIG. 5a, forming a photosensitive organic resin layer 300 between the basic pattern 200 of the pixel defining layer, the photosensitive organic resin layer 300 exposing the first pattern 200a.

S202. Subjecting the first pattern 200a exposed to a surface treatment with a self-assembled monomolecular layer.

S203. As shown in FIG. 5b, forming a fluorinated monomolecular layer 210 on the surface of the first pattern 200a, to form the pixel defining layer 20.

S204. Removing the photosensitive organic resin layer 300 to form the structure as shown in FIG. 3b.

In one aspect, forming the photosensitive organic resin layer 300 in regions other than the region in which the basic pattern 200 of the pixel defining layer is located may protect the pattern layers of other regions upon forming the fluorinated monomolecular layer 210; besides, by setting the thickness of the photosensitive organic resin layer 300, the thickness of the first pattern 200a can be determined so as to determine the range for forming the fluorinated monomolecular layer 210.

In another aspect, compared with other non-photosensitive organic materials, the photosensitive organic resin material employed in the embodiments of the present invention can simplify the process upon forming the organic resin layer 300.

On this basis, explanation may be made based on the following two conditions. The first condition is as follows.

In some embodiments, under the circumstance that the requirement for the height of the basic pattern 200 of the pixel defining layer is not high, an inorganic material may be directly employed to form the basic pattern 200 of the pixel defining layer, i.e., the above S01 may specifically comprise the steps of:

S101. forming a first film of inorganic material on a substrate 100.

S102. subjecting the first film to a patterning process to form the basic pattern 200 of the pixel defining layer that is comprised of the first pattern 200a and a second pattern 200b.

That is, the first pattern 200a and the second pattern 200b are formed integrally.

It shall be noted that the basic pattern 200 of the pixel defining layer formed by steps S101-S102 actually does not contain the dash line for distinguishing the first pattern 200a and the second pattern 200b in FIG. 3a. Dash lines are provided in the drawings of the present invention mainly for the purpose of facilitating to describe the range for forming the fluorinated monomolecular layer 210.

Under this circumstance, in some embodiments, the above S201 may specifically comprise the steps of:

S201a. As shown in FIG. 6a, forming a second film 300a of the photosensitive organic resin material on the substrate on which the basic pattern 200 of the pixel defining layer is formed, the second film 300a covering the basic pattern 200 of the pixel defining layer.

Herein, the photosensitive organic resin material may be, for example, an organic photoresist.

S201b. Etching the second film 300a with plasma to expose the first pattern 200a such that the second film between the basic pattern 200 of the pixel defining layer (that is, the second film in the pixel region defined by the pixel defining layer) is formed into the photosensitive organic resin layer 300 as shown in FIG. 5a.

Herein, by controlling the time of plasma etching, the height of the photosensitive organic resin layer 300 can be controlled, thereby determining the height of the first pattern 200a.

As such, compared with directly forming an organic resin layer 300, damage to pattern layers in other regions during subsequent self-assembling caused by non-uniform deposition upon forming an organic resin layer 300 may be avoided.

The second condition is as follows:

In some embodiments, under the circumstance that the requirement for the height of the basic pattern 200 of the pixel defining layer is strict, the basic pattern 200 of the pixel defining layer is formed using an organic material and an inorganic material, i.e., the above step S01 may specifically be as follows: forming the basic pattern 200 of the pixel defining layer that is comprised of the first pattern 200a and a third pattern of organic material on a substrate 100, wherein the first pattern 200a is located on or above the third pattern.

In some embodiments, forming the basic pattern 200 of the pixel defining layer that is comprised of the first pattern 200a and a third pattern of organic material as described above may be specifically achieved by the following steps:

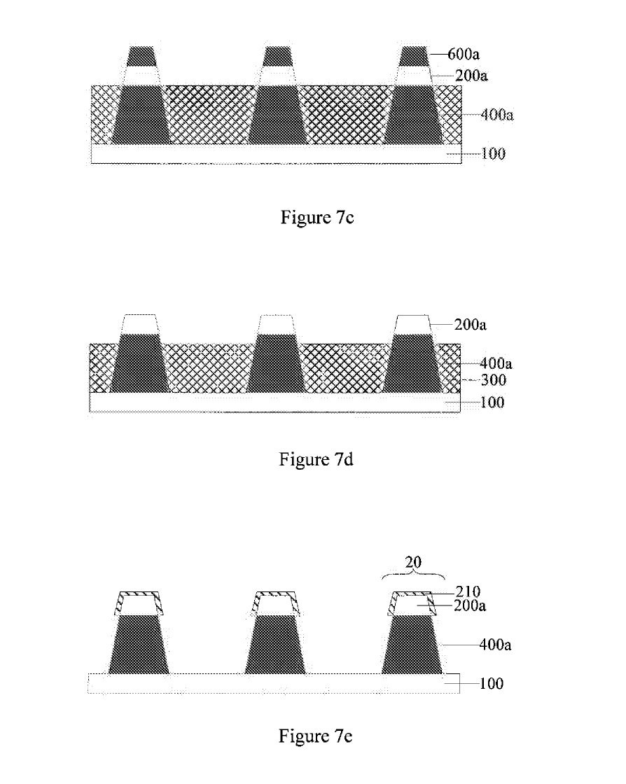

S111. As shown in FIG. 7a, sequentially forming a third film 400 of negative photosensitive organic resin material, a fourth film 500 of inorganic material and a fifth film 600 of negative photosensitive organic resin material on a substrate 100.

In some embodiments, a negative photosensitive organic resin material is employed for the material of the third film 400 such that the third pattern finally formed is the cured portion after exposure, i.e., the portion retained on the substrate is the cured portion and the portion not retained on the substrate is the uncured portion. As such, during subsequent cleaning and use, the structure thereof can be well maintained and good stability may be obtained.

S112. As shown in FIG. 7b, exposing the substrate on which the third film 400, the fourth film 500 and the fifth film 600 are formed by using an ordinary mask such that the cured portion in the third film 400 forms the third pattern 400a and the cured portion in the fifth film 600 forms a fifth pattern 600a, and removing the uncured portion in the fifth film after development.

Herein, under the circumstance of exposing the substrate on which the third film 400, the fourth film 500 and the fifth film 600 are formed by using an ordinary mask, the cured portion in the third film 400 forming the third pattern 400a, the cured portion, i.e., the fifth pattern 600a, in the fifth film 600 is necessarily located on top of the third pattern 400a. Therefore, as long as the third pattern 400a is defined, the position of the fifth pattern 600a is correspondingly defined.

The exposed region of the substrate can be controlled by controlling the position of the projection of the opening of the mask in the substrate.

S113. As shown in FIG. 7c, etching the fourth film 500 using the fifth pattern 600a as a mask to form the first pattern 200a, wherein the third pattern 400a and the first pattern 200a constitute the basic pattern 200 of the pixel defining layer.

Afterwards, as shown in FIG. 7d, removing the fifth pattern 600a such that the uncured portion in the third pattern 400 is formed into the photosensitive organic resin layer 300.

As such, the basic pattern 200 of the pixel defining layer can be formed by using a mask only once, and a photosensitive organic resin layer 300 between the basic pattern 200 of the pixel defining layer (that is, a photosensitive organic resin layer 300 in the pixel region defined by the pixel defining layer) is formed.

In this case, in some embodiments, a fluorinated monomolecular layer 210 is formed on the surface of the first pattern 200a to form the pixel defining layer 20. Then, the photosensitive organic resin layer 300 is removed to form the structure as shown in FIG. 7e.

On the above basis, fluorosilane may be employed to subject the first pattern 200a to the surface treatment with the self-assembled monomolecular layer. On this basis, prior to subjecting the first pattern 200a to the surface treatment with the self-assembled monomolecular layer with the fluorosilane, the method further comprises: subjecting the first pattern 200a to a hydroxylation treatment.

After the hydroxylation treatment, the first pattern 200a may react with a silane more easily.

Embodiments of the present invention further provide a pixel defining layer 20, as shown in FIG. 3b and FIG. 7e, the pixel defining layer 20 comprising: a basic pattern 200 of the pixel defining layer comprising a first pattern 200a of inorganic material, the first pattern 200a being the top part of the basic pattern 200 of the pixel defining layer; further comprising: a fluorinated monomolecular layer 210 self-assembled on a surface of the first pattern.

In some embodiments, as shown in FIG. 3b, the basic pattern 200 of the pixel defining layer may further comprise a second pattern 200b of inorganic material in addition to the first pattern 200a of inorganic material. Moreover, the first pattern 200a is located on or above the second patter 200b. Herein, distinguishing the first pattern 200a from the second pattern 200b is merely for facilitating to subsequently describe the structure of the fluorinated monomolecular layer 210. The dash lines that distinguish the first pattern 200a from the second pattern 200b in FIG. 3b actually do not exist.

As shown in FIG. 7e, in addition to the first pattern 200a of inorganic material, the basic pattern 200 of the pixel defining layer further comprises a third pattern 400a of organic material, the first pattern 200a being located on or above the third pattern 400a.

Embodiments of the present invention further provide a pixel defining layer 20, comprising: a basic pattern 200 of the pixel defining layer comprising a first pattern 200a of inorganic material, the first pattern 200a being the top part of the basic pattern 200 of the pixel defining layer; and further comprising: a fluorinated monomolecular layer 210 self-assembled on the surface of the first pattern. Because the self-assembled fluorinated monomolecular layer 210 is connected to the first pattern 200a via a covalent bond, placement over a long period of time, a general cleaning step (other than plasma), and processes such as annealing will not affect the lyophobic performance thereof. Therefore, the lyophobic performance of the pixel defining layer 20 formed by such a method can be maintained for a long time without worrying about out-of-service thereof.

In some embodiments, under the circumstance that the requirement for the height of the basic pattern 200 of the pixel defining layer is not strict, as shown in FIG. 3b, the basic pattern 200 of the pixel defining layer is formed by directly using an inorganic material, i.e., the basic pattern 200 of the pixel defining layer comprises the first pattern 200a of inorganic material and the second pattern 200b of inorganic material, and the first pattern 200a and the second pattern 200b are formed integrally. That is, the first pattern 200a and the second pattern 200b are formed by subjecting one film layer to a patterning process.

It shall be noted that the dash lines that distinguish between the first pattern 200a and the second pattern 200b in FIG. 3b actually do not exist. Dash lines are provided in the figures of the present invention mainly for the purpose of facilitating to describe the range for forming the fluorinated monomolecular layer 210.

In some embodiments, under the circumstance that the requirement for the height of the basic pattern 200 of the pixel defining layer is strict, as shown in FIG. 7e, the basic pattern 200 of the pixel defining layer is formed by using an organic material and an inorganic material, i.e., the basic pattern 200 of the pixel defining layer comprises the first pattern 200a of inorganic material and a third pattern 400a of organic material.

In some embodiments, the material of the third pattern 400a is a photosensitive organic resin material after being cured.

Embodiments of the present invention further provide a display substrate, comprising the above pixel defining layer 20.

The display substrate may be a display substrate which can form corresponding pattern layers by ink-jet printing, such as an array substrate for OLED or a color filter substrate for a liquid crystal display.

Embodiments of the present invention further provide a display apparatus, comprising the above display substrate.

The display apparatus may be a display device such as a liquid crystal display, electronic paper, OLED, a polymer light-emitting diode (PLED), etc., and any product or component having display function such as a TV set, a digital camera, a mobile phone or a tablet computer including these display devices.

Embodiments of the present invention further provide a method for preparing a display substrate, comprising forming a pixel defining layer 20 on a substrate 100, wherein the method for preparing a pixel defining layer 20 is the above method for preparing a pixel defining layer 20.

Illustratively, taking a display substrate for OLED as an example, the preparation method comprises:

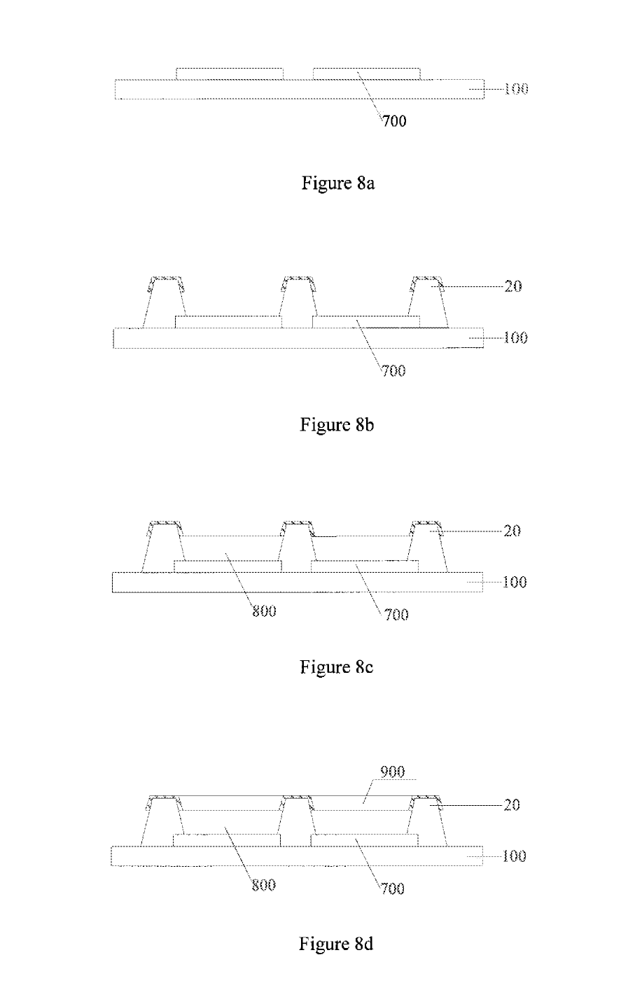

S301. As shown in FIG. 8a, forming a first electrode 700 on the pixel region of the substrate 100 by a patterning process.

The first electrode 700 generally can be an anode, or sometimes a cathode.

S302. As shown in FIG. 8b, forming a pixel defining layer 20 on the non-pixel region of the substrate 100.

The method for preparing a pixel defining layer 20 usually employs the above method for preparing a pixel defining layer 20, and no further detail will be given herein.

S303. As shown in FIG. 8c, forming an organic material functional layer 800 on the first electrode in the pixel region defined by the pixel defining layer 20.

As to the organic material functional layer 800, it may at least comprise a light-emitting layer, and may further comprise an electron transport layer and a hole transport layer. On this basis, in order to improve the efficiency of injecting electrons and holes to a light-emitting layer, the organic material functional layer may further comprise an electron injection layer disposed between the cathode and the electron transport layer, and a hole injection layer disposed between the hole transport layer and the anode.

The organic material functional layer 800 may be formed by ink-jet printing.

S303. As shown in FIG. 8d, forming a second electrode layer 900 on the organic material functional layer 800.

The second electrode layer 900 generally can be a cathode, or sometimes an anode.

The present invention includes the following embodiments:

### Embodiment 1

A display substrate comprising a pixel defining layer, wherein

The pixel defining layer comprises: a basic pattern of the pixel defining layer comprising a first pattern of inorganic material, the first pattern being the top part of the basic pattern of the pixel defining layer; and

the pixel defining layer further comprises: a fluorinated monomolecular layer self-assembled on a surface of the first pattern.

### Embodiment 2

The display substrate of Embodiment 1, wherein the basic pattern of the pixel defining layer further comprises a second pattern of inorganic material, and the first pattern and the second pattern are formed integrally.

### Embodiment 3

The display substrate of Embodiment 1, wherein the basic pattern of the pixel defining layer comprises the first pattern of inorganic material and a third pattern of organic material.

### Embodiment 4

The display substrate of Embodiment 3, wherein a material of the third pattern is a photosensitive organic resin material after being cured.

### Embodiment 5

The display substrate of Embodiment 3 or 4, wherein the basic pattern of the pixel defining layer is comprised of the first pattern and the third pattern.

### Embodiment 6

The display substrate of Embodiment 2, wherein the inorganic material of the first pattern is same as the inorganic material of the second pattern.

### Embodiment 7

The display substrate of any one of Embodiments 1-6, wherein the display substrate comprises a pixel region and a non-pixel region, the basic pattern of the pixel defining layer corresponding to the non-pixel region.

### Embodiment 8

The display substrate of any one of Embodiments 1-7, wherein the display substrate is an array substrate for OLED or a color filter substrate for a liquid crystal display.

### Embodiment 9

The display substrate of Embodiment 1, wherein the inorganic material is selected from the group consisting of silicon (Si), silicon dioxide (SiO₂), silicon nitride (SiNₓ), and combinations thereof.

### Embodiment 10

The display substrate of Embodiment 4, wherein the photosensitive organic resin material is selected from a positive photoresist and a negative photoresist. Common positive photoresists include BP212 series which are widely used, and the like; and common negative photoresists include SU 8 series which are widely used, and the like. Further examples include positive photoresists from DONGJIN SEMICHEM Co., Ltd.: positive photoresist series such as DSAM 3037 and DSAM3020; negative photoresists from DONGJIN SEMICHEM Co., Ltd.: negative photoresist series such as DNR-L300D1.

### Embodiment 11

A method for preparing a display substrate comprising forming a pixel defining layer on a substrate, wherein forming the pixel defining layer comprises:

forming a basic pattern of the pixel defining layer on the substrate; the basic pattern of the pixel defining layer comprises a first pattern of inorganic material, the first pattern being the top part of the basic pattern of the pixel defining layer; and

subjecting the first pattern to a surface treatment with a self-assembled monomolecular layer to form a fluorinated monomolecular layer on a surface of the first pattern, and thus form the pixel defining layer.

### Embodiment 12

The method of Embodiment 11, wherein subjecting the first pattern to a surface treatment with a self-assembled monomolecular layer comprises:

forming a photosensitive organic resin layer between the basic pattern of the pixel defining layer (that is forming a photosensitive organic resin layer in the pixel region defined by the pixel defining layer), the photosensitive organic resin layer exposing the first pattern;

subjecting the first pattern to the surface treatment with the self-assembled monomolecular layer to form the fluorinated monomolecular layer; and

removing the photosensitive organic resin layer after the fluorinated monomolecular layer has been formed on the surface of the first pattern.

### Embodiment 13

The method of Embodiment 12, characterized in that forming the basic pattern of the pixel defining layer on the substrate comprises:

forming a first film of inorganic material on the substrate; and

subjecting the first film to a patterning process to form the basic pattern of the pixel defining layer that is comprised of the first pattern and a second pattern.

### Embodiment 14

The method of Embodiment 13, characterized in that “forming a photosensitive organic resin layer between the basic pattern of the pixel defining layer, the photosensitive organic resin layer exposing the first pattern” comprises:

forming a second film of photosensitive organic resin material on the substrate on which the basic pattern of the pixel defining layer is formed, the second film covering the basic pattern of the pixel defining layer; and

etching the second film by plasma to expose the first pattern such that the second film between the basic pattern of the pixel defining layer is formed into the photosensitive organic resin layer.

### Embodiment 15

The method of Embodiment 12, wherein forming the basic pattern of the pixel defining layer on the substrate comprises:

forming the basic pattern of the pixel defining layer that is comprised of the first pattern and a third pattern of organic material on the substrate.

### Embodiment 16

The method of Embodiment 15, wherein forming the basic pattern of the pixel defining layer that is comprised of the first pattern and the third pattern of organic material on the substrate comprises:

sequentially forming a third film of negative photosensitive organic resin material, a fourth film of inorganic material and a fifth film of negative photosensitive organic resin material on the substrate;

exposing the substrate on which the third film, the fourth film and the fifth film are formed by using an ordinary mask such that the cured portion in the third film forms the third pattern and the cured portion in the fifth film forms a fifth pattern, and removing the uncured portion in the fifth film after development; and

etching the fourth film by using the fifth pattern as a mask to form the first pattern; wherein the third pattern and the first pattern constitute the basic pattern of the pixel defining layer;

forming the photosensitive organic resin layer between the basic pattern of the pixel defining layer comprises:

forming the uncured portion in the third film into the photosensitive organic resin layer after removing the fifth pattern.

### Embodiment 17

The method according to any one of Embodiments 11 to 16, characterized in that the first pattern is subjected to the surface treatment with the self-assembled monomolecular layer with a fluorosilane;

the method further comprising: subjecting the first pattern to a hydroxylation treatment prior to subjecting the first pattern to the surface treatment with the self-assembled monomolecular layer with a fluorosilane.

### Embodiment 18

The method of Embodiment 17, wherein the fluorosilane has the formula Si(R1)₄, wherein each R1 is independently selected from halogen or fluoroalkyl, and at least one R1 is halogen and at least one R1 is fluoroalkyl.

### Embodiment 19

The method of Embodiment 18, wherein the fluorosilane is

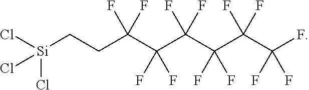 [SMILES: FC(F)(F)C(F)(F)C(F)(F)C(F)(F)C(F)(F)C(F)(F)CC[Si](Cl)(Cl)Cl]

### Embodiment 20

A display apparatus, comprising the display substrate according to any one of Embodiments 1-10.

### Embodiment 21

The display apparatus of Embodiment 20, wherein the display apparatus is a liquid crystal display, electronic paper, OLED, polymer light-emitting diode (PLED), or a TV set, a digital camera, a mobile phone or a tablet computer comprising at least one of the foregoing display apparatuses.

The above are merely exemplary embodiments of the present invention, and are not intended to limit the scope of protection of the present invention, which is yet determined by the appended claims.

The present application claims the priority of the Chinese patent application No. 201510108888.5 submitted on Mar. 12, 2015, and the content disclosed in the above Chinese patent application is incorporated herein by reference as part of the present application.

1. A display substrate comprising a pixel defining layer, wherein
the pixel defining layer comprises: a basic pattern of the pixel defining layer comprising a first pattern of inorganic material, the first pattern being a top part of the basic pattern of the pixel defining layer; and
the pixel defining layer further comprises: a fluorinated monomolecular layer self-assembled on a surface of the first pattern.

2. The display substrate of claim 1, wherein the basic pattern of the pixel defining layer further comprises a second pattern of inorganic material, and the first pattern and the second pattern are formed integrally.

3. The display substrate of claim 1, wherein the basic pattern of the pixel defining layer comprises the first pattern of inorganic material and a third pattern of organic material.

4. The display substrate of claim 3, wherein a material of the third pattern is a photosensitive organic resin material after being cured.

5. The display substrate of claim 3, wherein the basic pattern of the pixel defining layer is comprised of the first pattern and the third pattern.

6. The display substrate of claim 2, wherein the inorganic material of the first pattern is the same as the inorganic material of the second pattern.

7. The display substrate of claim 1, wherein the display substrate comprises a pixel region and a non-pixel region, the basic pattern of the pixel defining layer corresponding to the non-pixel region.

8. (canceled)

9. The display substrate of claim 1, wherein the inorganic material is selected from the group consisting of silicon (Si), silicon dioxide (SiO₂), silicon nitride (SiNₓ), and combinations thereof.

10. The display substrate of claim 4, wherein the photosensitive organic resin material is positive photoresist or a negative photoresist.

11. A method for preparing a display substrate comprising forming a pixel defining layer on a substrate, wherein forming the pixel defining layer comprises:
forming a basic pattern of the pixel defining layer on the substrate; the basic pattern of the pixel defining layer comprises a first pattern of inorganic material, the first pattern being a top part of the basic pattern of the pixel defining layer; and
subjecting the first pattern to a surface treatment with a self-assembled monomolecular layer to form a fluorinated monomolecular layer on a surface of the first pattern, and thus form the pixel defining layer.

12. The method of claim 11, wherein subjecting the first pattern to a surface treatment with the self-assembled monomolecular layer comprises:
forming a photosensitive organic resin layer between the basic pattern of the pixel defining layer, the photosensitive organic resin layer exposing the first pattern;
subjecting the first pattern to the surface treatment with the self-assembled monomolecular layer to form the fluorinated monomolecular layer; and
removing the photosensitive organic resin layer after the fluorinated monomolecular layer has been formed on the surface of the first pattern.

13. The method of claim 12, wherein forming the basic pattern of the pixel defining layer on the substrate comprises:
forming a first film of inorganic material on the substrate; and
subjecting the first film to a patterning process to form the basic pattern of the pixel defining layer that is comprised of the first pattern and a second pattern.

14. The method of claim 13, wherein forming a photosensitive organic resin layer between the basic pattern of the pixel defining layer, the photosensitive organic resin layer exposing the first pattern comprises:
forming a second film of photosensitive organic resin material on the substrate on which the basic pattern of the pixel defining layer is formed, the second film covering the basic pattern of the pixel defining layer; and
etching the second film by plasma to expose the first pattern such that the second film between the basic pattern of the pixel defining layer is formed into the photosensitive organic resin layer.

15. The method of claim 12, wherein forming the basic pattern of the pixel defining layer on the substrate comprises:
forming the basic pattern of the pixel defining layer that is comprised of the first pattern and a third pattern of organic material on the substrate.

16. The method of claim 15, wherein forming the basic pattern of the pixel defining layer that is comprised of the first pattern and the third pattern of organic material on the substrate comprises:
sequentially forming a third film of negative photosensitive organic resin material, a fourth film of inorganic material and a fifth film of negative photosensitive organic resin material on the substrate;
exposing the substrate on which the third film, the fourth film and the fifth film are formed by using an ordinary mask such that the cured portion in the third film forms the third pattern and the cured portion in the fifth film forms a fifth pattern, and removing the uncured portion in the fifth film after development; and
etching the fourth film by using the fifth pattern as a mask to form the first pattern; wherein the third pattern and the first pattern constitute the basic pattern of the pixel defining layer;
forming the photosensitive organic resin layer between the basic pattern of the pixel defining layer comprises:
forming the uncured portion in the third film into the photosensitive organic resin layer after removing the fifth pattern.

17. The method according to claim 11, wherein the first pattern is subjected to a surface treatment with the self-assembled monomolecular layer with a fluorosilane;
the method further comprising: subjecting the first pattern to a hydroxylation treatment prior to subjecting the first pattern to a surface treatment with the self-assembled monomolecular layer with the fluorosilane.

18. The method of claim 17, wherein the fluorosilane has the formula Si(R1)₄, wherein each R1 is independently selected from halogen or fluoroalkyl, and at least one R1 is halogen and at least one R1 is fluoroalkyl.

19. The method of claim 18, wherein the fluorosilane is

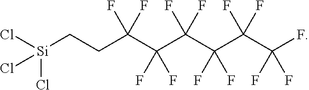 [SMILES: FC(F)(F)C(F)(F)C(F)(F)C(F)(F)C(F)(F)C(F)(F)CC[Si](Cl)(Cl)Cl]

20. A display apparatus, comprising the display substrate of claim 1.

21. The display apparatus of claim 20, wherein the display apparatus is a liquid crystal display, electronic paper, organic light-emitting diode (OLED), polymer light-emitting diode (PLED), a TV set, a digital camera, a mobile phone or a tablet computer.
